(19) United States
(12) Patent Application Publication
(10) Pub. No.: US 2025/0189960 A1
(43) Pub. Date: Jun. 12, 2025

(54) COMPUTER-IMPLEMENTED METHOD FOR SIMULATING A MULTIPHASE ELECTRIC DRIVE HAVING ENERGIZABLE STRINGS, USING A HARDWARE-IN-THE-LOOP SIMULATOR FOR TESTING A POWER ELECTRONIC CONTROL DEVICE WITH AN INTEGRATED INVERTER

(71) Applicant: dSPACE GmbH, Paderborn (DE)

(72) Inventor: Stefan GENG, Paderborn (DE)

(73) Assignee: dSPACE GmbH, Paderborn (DE)

(21) Appl. No.: 18/977,863

(22) Filed: Dec. 11, 2024

(30) Foreign Application Priority Data
Dec. 11, 2023 (DE) 10 2023 134 664.4

(51) Int. Cl. G05B 23/02; G01R 31/40

(52) U.S. Cl. CPC G05B 23/0243; G01R 31/40

(57) ABSTRACT

A computer-implemented method for simulating a multiphase electric drive having energizable strings, using a hardware-in-the-loop simulator for testing a power electronic control device with an integrated inverter is provided. The simulator, based on a mathematical model of the electric drive, computes the string currents in the strings of the drive, and an electrical reactive potential of the potential-free string terminal resulting from the drive reaction. The potential-free string terminal is set to the reactive potential by a voltage emulator. The method reduces the influence of inaccurately computed reactive potentials on the simulation by supplementing the mathematical model of the electric drive in the strings in each case by a virtual switch. The virtual switches in the open state reduce the influence of the measured string voltages on the computed current flows. The virtual switches in the strings of the electric drive are opened and/or closed by a switching logic.

This nonprovisional application claims priority under 35 U.S.C. § 119 (a) to German Patent Application No. 10 2023 134 664.4, which was filed in Germany on Dec. 11, 2023, and which is herein incorporated by reference.

### BACKGROUND OF THE INVENTION

### Field of the Invention

The invention relates to a computer-implemented method for simulating a multiphase electric drive having energizable strings, using a hardware-in-the-loop simulator for testing a power electronic control device with an integrated inverter, wherein the control device has at least three supply terminals, and in test mode, in time segments the inverter of the control device switches one supply terminal of the three supply terminals to a high inverter potential, switches another supply terminal of the three supply terminals to a low inverter potential, and switches yet another supply terminal of the three supply terminals potential-free, wherein in test mode the supply terminals of the control device are connected to corresponding string terminals of the simulator, wherein the string voltages of the string terminals in the simulator are metrologically detected, wherein the simulator, based on the measured string voltages, computes corresponding string currents of the drive using a mathematical model of the electric drive and its strings, wherein by evaluating the string voltages and/or the string currents, in the simulator it is determined which string terminal is connected to the potential-free supply terminal of the control device and therefore is a potential-free string terminal, wherein the simulator determines an electrical reactive potential of the potential-free string terminal, which results from the drive reaction, and by means of a voltage emulator sets the potential-free string terminal to the determined reactive potential, and the simulator feeds the computed string currents into the nonpotential-free string terminals by use of a current emulator.

### Description of the Background Art

A computer-implemented method has become established in the technical field of real-time simulation of electrical circuits, in the present case in the form of a multiphase electric drive, for the purpose of influencing or testing power electronic control devices, which are used in large numbers in motor vehicles, aircraft, and power generation or power distribution facilities, etc. The application of the computer-implemented method under consideration is hardware-in-the-loop (HIL) simulation. When the above-described computer-implemented method is carried out within the scope of an HIL simulation, the simulation is performed on a processing unit, or optionally on multiple processing units, of the HIL simulator by computing the mathematical model of the electric drive. i.e., a model in the form of equations that are numerically computable on a computer. For the attached power electronic control device, the HIL simulator simulates the technical environment in which the control device to be tested, i.e., the multiphase electric drive in this case, is to actually be used afterward.

Since in the present case the testing of the control device takes place on the power level, the simulator, in addition to the mathematical model of the drive, which is computed on a suitable processing unit, also includes power electronic components, namely, in the form of the stated voltage emulators and current emulators. In test mode, the control device is electrically connected to the simulator by connecting the supply terminals of the control device to corresponding string terminals of the simulator, as described above.

In the simulator, the string voltages at the string terminals are metrologically detected. The measured string voltages are (in any case also) numerical input variables of the mathematical model of the electric drive, which are then used to compute the electrical and mechanical state variables of the drive. The electrical state variables include the resulting string currents in the strings of the simulated drive. Depending on the operating state of the drive, electrical power may be driven by the control device into the simulator (motor mode of the drive), or also electrical power may be driven by the simulator into the control device (generator mode of the drive). Thus, the term “supply terminals of the control device” is not to be construed as limiting with regard to a direction of the energy flow.

The inverter of the control device is supplied via a DC link, which provides the high and low inverter potentials. As a result of switching the various inverter potentials to the supply terminals of the control device in a certain time sequence, voltage-time integrals, and thus desired currents in conjunction with attached coils, may be achieved there in a targeted manner. It is important here that the power electronic control device together with the inverter implements an excitation pattern in which one of the supply terminals, which relates to the direct influence of the control device, is switched potential-free, i.e., is connected to neither the high nor the low inverter potential, but instead is separated with high impedance from the inverter potentials; the supply terminal in question is “floating,” and current cannot flow across it. Such excitation patterns are used, for example, to activate permanently excited three-phase current synchronous machines, which in practice are often brushless direct current (brushless DC (BLDC)) motors that are activated via block commutation.

The supply terminal of the control device, which with regard to the effect of the control device is switched potential-free, and therefore also of course the corresponding string terminal of the simulator connected to this string terminal, carry no electrical potential that is directly specified by the control device. Rather, the electrical potential at these terminals, for a genuine electric drive, is determined by the drive reaction, i.e., the electromotive countervoltage that is induced in the enabled string. For the simulated drive, by evaluation of the string voltages and/or the string currents it is determined which of the string terminals is connected to the potential-free supply terminal of the control device, and therefore is the potential-free string terminal. The electrical reactive potential of the potential-free string terminal resulting from the drive reaction is then determined using the mathematical model of the drive, and the voltage emulator is used to set the potential-free string terminal to the determined reactive potential. By use of the current emulator, the simulator supplies the computed string currents to the nonpotential-free string terminals, via which currents can also flow due to the fact that in the control device they are each connected to one of the inverter potentials.

The computation of the reactive potential that results from the drive reaction usually takes place based on certain assumptions. One example of a frequent underlying assumption is that the simulated drive is magnetically symmetrical, i.e., the inductances of the windings of the strings of the energizable drive are equal. In the fixed-rotor dq coordinate system having only two phases (since for a star circuit of the drive trains, the electrical values of one drive train always result from the electrical values of the other two strings), this means that for the transformed inductances Ld, Lq, the expression Ld=Lq applies. However, if this is not the case, the reactive potentials may possibly be incorrectly computed, which for the simulator may result in incorrectly computed string currents (even in the actual potential-free and currentless string).

### SUMMARY OF THE INVENTION

It is therefore an object of the present invention to provide a method for simulating a multiphase drive and the corresponding simulator in such a way that the influence of inaccurately computed reactive potentials on the simulation is reduced.

For the method, the derived object is achieved, firstly, by supplementing the mathematical model of the electric drive in the strings by a virtual switch in each case, wherein the virtual switches in the open state reduce the influence of the associated measured string voltages on the computed current flows in the particular string, and wherein the virtual switches in the strings of the electric drive are opened and/or closed by a switching logic of the simulator by evaluating at least one string voltage and/or string current.

By use of the virtual switches, the influence of an incorrect string voltage (or also multiple incorrect string voltages), which is/are metrologically determined and relayed as a measured string voltage to the mathematical model of the drive and thus also has/have an influence on the computation of the string currents, may be reduced, namely, by opening the virtual switch in question, i.e., the switch in the drive train at which the incorrect string voltage is present. By means of the switching logic of the simulator and the associated evaluation of at least one string voltage and/or string current, the virtual switches in the strings of the electric drive may be activated, i.e., opened and/or closed, as needed in order to reduce in a targeted manner the influence of the incorrect string voltage on the mathematical model within the scope of the computation of the model.

The virtual switch in the model of a string of the drive can be represented by an ohmic resistor whose resistance value is a function of the switching state of the virtual switch. As a result, it is not necessary to change over the structure of the mathematical model when the switching state of a virtual switch or also multiple virtual switches changes. This means that the structure of the equations underlying the mathematical model remains unchanged, and only parameters of the model, i.e., the resistance values of the virtual switches, are varied as a function of the switching state.

The switching logic of the simulator can recognize the string terminal that is potential-free, i.e., is connected to the potential-free supply terminal of the control device, and opens the virtual switch of the string whose string terminal is potential-free. This particular example focuses on the problem that the reactive potential resulting from the drive reaction is not correctly computed, and therefore the electrical potential which the voltage emulator applies to the potential-free string terminal is not correctly set.

The switching logic of the simulator can evaluate whether a requirement for correctly determining the reactive potential at the potential-free string terminal is met in the actual operating state of the electric drive, and if the requirement for correctly determining the reactive potential is not met, the switching logic of the simulator opens the virtual switch of the string whose string terminal is potential-free. By use of this measure, employing the virtual switch is possible in a targeted manner, namely, limited to situations in which the requirement for correctly determining the reactive potential is not met. The switching logic could examine the mathematical model of the electric drive to determine, for example, whether the electric drive is magnetically symmetrical, i.e., whether the inductances Ld, Lq in the strings of the drive in the two-phase dq system are equal (Ld=Lq).

The resistance values of the virtual switches for the open and the closed switching states can be selected in such a way that the mathematical model of the electric drive may be solved in a stable manner using explicit numerical solution methods, in particular for a predefined computation increment, preferably under real-time conditions.

An implicit numerical method may be applied to the motor model. In this case, the resistance values may be selected over a wide range. Since every integration step involves additional computation effort (an iterative method for solving the numerical implicit equation, or an analytical method with matrix inversion which is then necessary), conflicts may possibly arise with real-time requirements for the computation.

The described method is preferably used in conjunction with a simulated electric drive, which is a multiphase, in particular three-phase, permanently excited synchronous machine, which in particular is a brushless direct current motor. The strings of the drive are generally interconnected in a star or triangle configuration.

The object derived above is further achieved using a hardware-in-the-loop simulator for computer-implemented simulation of a multiphase electric drive having energizable strings for testing a power electronic control device with an integrated inverter, to carry out the method described above. The control device is not part of the simulator; however, the operating principle of the simulator is understandable only in interaction with the control device. The control device has at least three supply terminals, and in test mode, in time segments the inverter of the control device switches one supply terminal of the three supply terminals to a high inverter potential, switches another supply terminal of the three supply terminals to a low inverter potential, and switches yet another supply terminal of the three supply terminals potential-free, wherein in test mode, i.e., when testing of the control device is carried out by the simulator, the supply terminals of the control device are connected to corresponding string terminals of the simulator. The string voltages of the string terminals are metrologically detected in the simulator, wherein the simulator computes corresponding string currents of the drive on a processing unit, using a mathematical model of the electric drive and its strings, based on the measured string voltages. By evaluating the string voltages and/or the string currents, in the simulator it is determined which string terminal is connected to the potential-free supply terminal of the control device and therefore is a potential-free string terminal. The simulator determines the electrical reactive potential of the potential-free string terminal, which results from the drive reaction. By means of a voltage emulator the simulator sets the potential-free string terminal to the determined reactive potential, and the simulator feeds the computed string currents into the nonpotential-free string terminals by use of a current emulator. The simulator is designed in such a way that in test mode, i.e., with the power electronic control device attached, it carries out the method described in detail above.

The invention further relates to a computer program that includes commands which, when the program is executed by a processing unit of a hardware-in-the-loop simulator, prompts the processing unit to carry out the method explained above.

In particular, there are numerous possibilities for designing and refining the method according to the invention for simulating a multiphase electric drive having energizable strings, using a hardware-in-the-loop simulator, and a corresponding hardware-in-the-loop simulator for testing a power electronic control device. Reference is made on the one hand to the claims that are subordinate to the independent claims, and on the other hand, to the following description of examples in conjunction with the drawings.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically shows a computer-implemented method for simulating a multiphase electric drive having energizable strings, using a hardware-in-the-loop simulator for testing a power electronic control device, and a corresponding simulator with an attached control device,

FIG. 2 shows computed string voltages and string currents for a magnetically asymmetrical drive (Ld not equal to Lq), once under the incorrect assumption of a magnetically symmetrical drive, and once when correctly taking into account the magnetic asymmetry of the drive,

FIG. 3 shows a method for simulating the electric drive using virtual switches, and

FIG. 4 shows the method according to FIG. 3 when the virtual switches are implemented as ohmic resistors with variable resistance values that are a function of the switching state of the particular virtual switch.

### DETAILED DESCRIPTION

The figures schematically illustrate various aspects of a computer-implemented method 1 for simulating a multiphase electric drive having energizable strings, using a hardware-in-the-loop simulator 2 for testing a power electronic control device 3 with an integrated inverter 4.

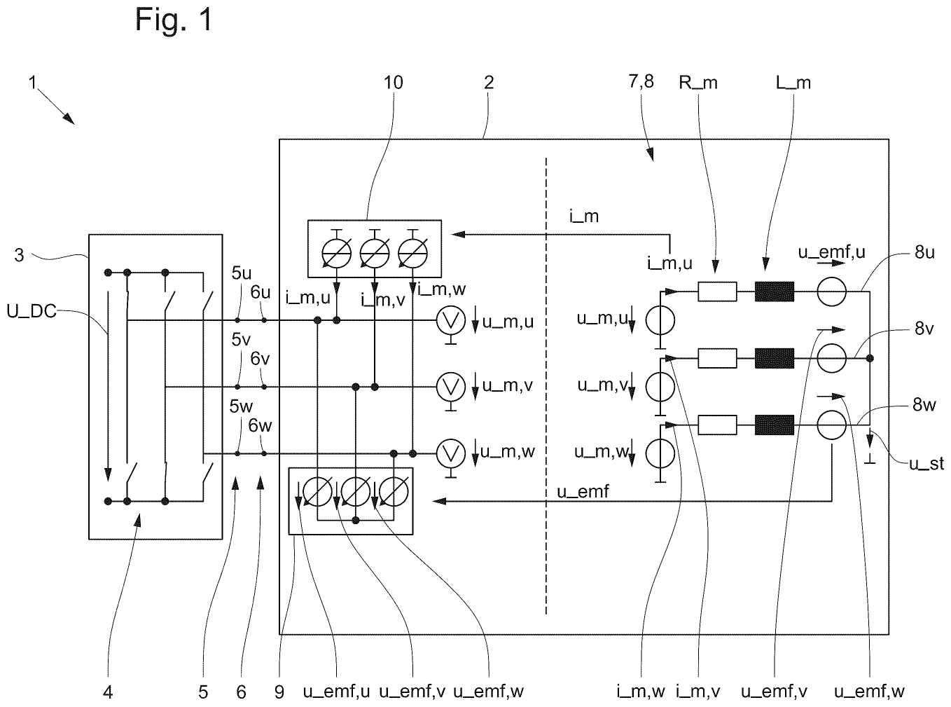

FIG. 1 shows a method 1 and a simulator 2 that is used to implement the method 1. The simulator 2 and the control device 3 to be tested are physically present as mutually connected devices. The multiphase drive to be simulated is not present per se; the electrical behavior of the drive is simulated by the simulator 2. The arrangement accordingly allows testing of the power electronic control device 3, which typically is a control device that is mass-produced or under development, without the control device 3 being connected to its actual operational environment, and without the actual operational environment having to be available at all, which is the significant advantage of hardware-in-the-loop simulations.

The inverter potentials of the inverter 4 contained in the control device 3 are formed by a DC link direct voltage U_DC. The control device is generally externally supplied with power, from which the DC link voltage U_DC may be directly or indirectly derived.

The control device 3 has three supply terminals 5, wherein in test mode, in time segments the inverter 4 of the control device 3 switches one supply terminal 5u of the three supply terminals 5 to a high inverter potential, switches another supply terminal 5v of the three supply terminals 5 to a low inverter potential, and switches yet another supply terminal 5w of the three supply terminals 5 potential-free. FIG. 1 shows only one switching configuration of the inverter as an example; it is naturally understood that the three supply terminals 5 of the control device 3 are acted on or switched potential-free in alternation with the low and the high inverter potential, which corresponds to the known operating principle of inverters.

In test mode the supply terminals 5u, 5v, 5w of the control device 3 are connected to corresponding string terminals 6u, 6v, 6w of the simulator 2, so that the control device 3 can physically interact with the simulator 2. The string voltages u_m,u, u_m,v, u_m,w of the string terminals 6u, 6v, 6w are metrologically detected in the simulator 2. Based on the measured string voltages u_m, the simulator 2 computes corresponding string currents i_m of the drive, using a mathematical model 7 of the electric drive and its strings 8.

In the present case, the simulated electric drive is a three-phase permanently excited synchronous machine. The mathematical model 7 of the electric drive is symbolized in FIG. 1 by an electrical equivalent circuit diagram of the electric drive of three drive trains 8 that are star-connected. Each drive train 8 is described in the electrical equivalent circuit diagram by a series connection of an ohmic string resistor R_m, a string inductor L_m, and the reactive voltage u_emf that is induced in the particular string 8. The respective string voltage u_m is present at the input of each drive train 8, i.e., at the side of the series connection facing away from the star point.

The transfer of the equivalent circuit by equations is then depicted by the mathematical model 7, by means of which the state variables of the electric drive may be computed.

By evaluating the string voltages u_m and/or the string currents i_m, it is determined in the simulator 2, in a manner known per se, which string terminal 6 is connected to the potential-free supply terminal 5w of the control device 3 and therefore is a potential-free string terminal 6w. This is important for the simulation of the electric drive, since the potential-free string terminal 6w and the potential-carrying terminals 6u, 6v are treated differently. The simulator 2 computes an electrical reactive potential u_emf,w of the potential-free string terminal 6w, resulting from the drive reaction, and by use of a voltage emulator 9 sets the potential-free string terminal 6w to the determined reactive potential u_emf,w. It should be noted here that the reactive potentials u_emf are not referenced to ground (in contrast to the string voltages u_m), and instead have the shared star point of the strings of the drive as a reference point, which is also illustrated this way in the figures. In general, the voltage u_m results at the exposed string terminal 6 due to superimposition of the voltages u_m at the switched supply terminals 5 (or at the corresponding string terminals 6) and the reactive potentials u_emf,which are in each case connected via the voltage emulator. The simulator 2 supplies the computed string currents i_m,u, i_m,v to the nonpotential-free string terminals 6u, 6v by means of a current emulator 10. In this regard, FIG. 1 is also schematic, since further details for implementing the simulation have been omitted for the sake of clarity. Thus, for example, it is not illustrated that switches are customarily provided between the terminals of the current emulator 9 and the string terminals 6 of the simulator 2 (and also switches between the terminals of the voltage emulator 9 and the string terminals 6 of the simulator 2), which allow the particular power source that is connected to the potential-free string terminal 6w to be disconnected from the potential-free string terminal 6w, thus preventing the current emulator 10 and the voltage emulator 9 from working against one another on a string terminal.

It has been explained at the outset that a problematic situation may arise when certain requirements for computing the reactive potentials resulting from the drive reaction are not met or are not adequately met, so that the reactive potentials are not correctly computed, which in turn may adversely affect the computation of the string currents. To clarify the problem, the electrical relationships of the equivalent circuit indicated in FIG. 1 is considered according to equations. It is assumed that the strings 8u, 8v are energized, and the string 8w is switched potential-free by the control device 3 and is thus currentless (except for currents briefly flowing across free-wheeling diodes in the inverter). Therefore, the string voltage u_m,w and the reactive voltage u_emf,w are of interest. For the star point voltage, consideration of the strings 8u and 8v results in the following (equation 1):

$$u\_m , w = u\_emf , w + \frac{1}{2} ( u\_m , u + u\_m , v - u\_emf , u - u\_emf , v )$$

The relationship u_m,w=u_emf,w+u_st applies for the string voltage u_m,w of the string 8w that is switched potential-free and is currentless. Assuming for simplicity that R_m,u equals R_m,v, and the knowledge that i_m,u equals −i_m,v, results in the following (equation 2):

$$u\_st = \frac{1}{2} ( - u\_emf , u - u\_emf , v - L\_m , u \frac{di\_m , u}{d t} - L\_m , v \frac{di\_m , v}{d t} … - R\_m , u \cdot i\_m , u - R\_m , v \cdot i\_m , v + u\_m , u + u\_m , v )$$

If only the fundamental wave of the magnetic flux is taken into account in the drive and is based on a magnetically symmetrical machine, the inductances L_m may be regarded as identical constants due to the symmetry properties of the three-phase system; i.e., L_m,u=L_m,v=Lm,w. In the fixed-rotor dq coordinates which are customarily used for the mathematical description of electric drives, Ld=Lq then corresponding applies. The voltage drops caused by the inductances cancel one another out, so that for the assumption of a magnetically symmetrical machine the following applies (equation 3):

$$u\_m , w = u\_emf , w + \frac{1}{2} ( - u\_emf , u - u\_emf , v + L\_m , u \frac{di\_m , v}{d t} … - L\_m , v \frac{di\_m , v}{dt} + u\_m , u + u\_m , v )$$

The relationship naturally applies for any string that is switched potential-free, regardless of whether this is string 8u, 8v, or 8w. In the switching situation in FIG. 1, u_m,v corresponds to the low inverter potential, generally the electrical device ground, and u_m,u corresponds to the high inverter potential. This is not constant direct voltage, but, rather, is a high-frequency PWM signal for allowing the string current to be set in wide ranges.

In the example according to FIG. 1, the reactive potential of the string that is switched in each case in a floating manner, from the viewpoint of the control device 3, is computed according to equation 3, and the voltage emulator 9 connects a corresponding voltage to the floating string in question.

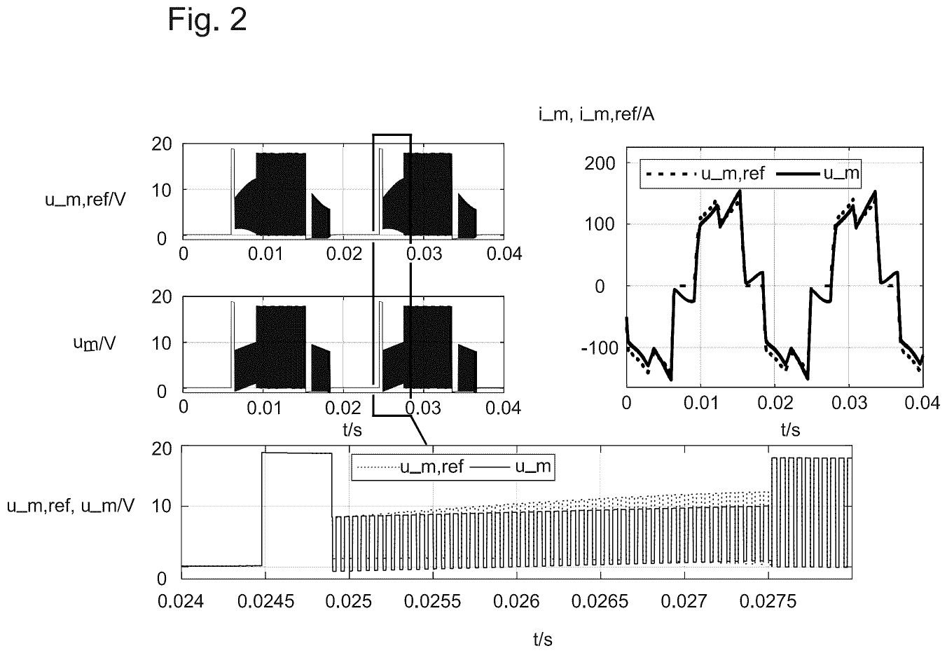

FIG. 2 shows a comparison of the computed string voltages u_m and the computed string currents i_m for an actual magnetically asymmetrical drive (Ld not equal to Lq), once under the incorrect assumption of a magnetically symmetrical drive (application of equation 3, curves u_m, i_m), and once when correctly taking into account the magnetic asymmetry of the drive (application of equation 2, curves u_m, ref, i_m, ref). The curve patterns at the top left show a string voltage over a time period greater than an inverter period, in which all strings have gone through all switching states of the inverter 4 twice. The voltage curves u_m and u_m, ref appear here as shaded areas, since the applied voltage is actually a high-frequency PWM signal, so that the voltage jumps back and forth between the top and bottom envelopes. The two voltages u_m and u_m, ref are illustrated together in an enlarged detail in the bottom image in FIG. 2, so that it is apparent that the voltages are variable with high frequency. In addition, it is apparent in the bottom image that the computations of the voltages are quite noticeably different from one another. This has an effect on the computation of the currents, as is apparent in the image at the top right in FIG. 2, where i_m, ref is the correctly computed string current, i.e., taking into account the magnetic asymmetry of the drive, and i_m is the incorrectly computed string current, for which the magnetic asymmetry of the drive has not been taken into account. Here as well, there are marked differences which show that the accuracy of the drive simulation is reduced when the requirements for a (simplified) computation of the reactive potentials are not met.

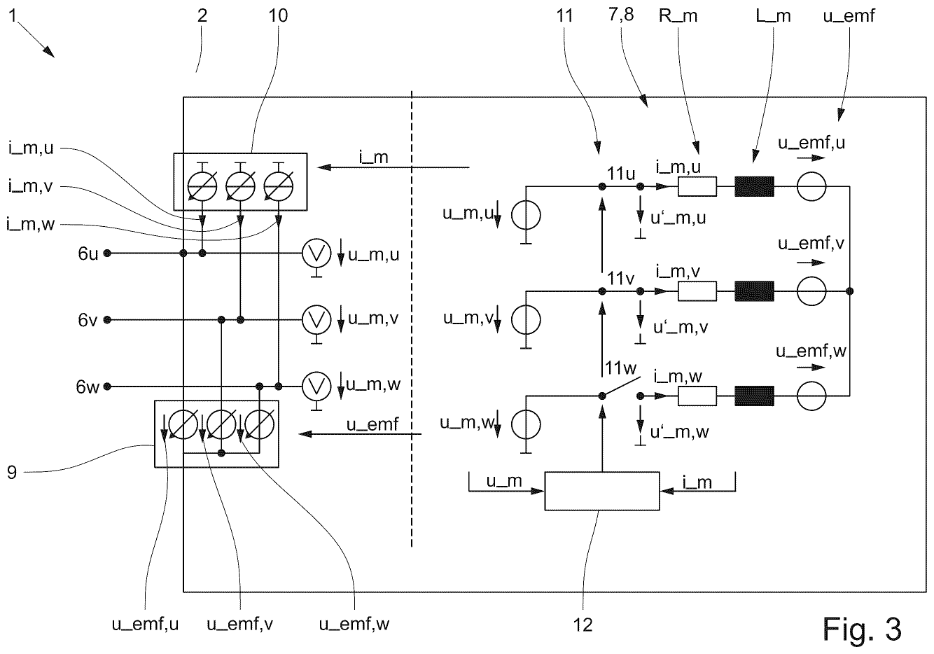

FIG. 3 illustrates a method 1 and a simulator 2 via which the above-described effects of an incorrect computation of the reactive potentials u_emf may be greatly reduced and even avoided. The illustration of the simulator 2 corresponds essentially to that of the simulator 2 in FIG. 1, but the control device has been omitted. To solve the problem, the mathematical model 7 of the electric drive in the strings 8 is supplemented in each case by a virtual switch 11, wherein the virtual switches 11 in the open state reduce the influence of the associated measured string voltages u_m on the computed current flows i_m in the particular string 8. The virtual switches 11 in the strings 8 of the electric drive are opened and/or closed by a switching logic 12 of the simulator 2 by evaluating at least one string voltage u_m and/or string current i_m.

In the illustrated case, the switching logic 12 of the simulator 2 is designed in such a way that it opens the virtual switch 11 of the string 8 whose string terminal 6 is potential-free. Proceeding from the conditions in FIG. 1, the supply terminals 5u, 5v of the control device 2 are then set to a defined electrical potential, which consequently also applies for the string terminals 6u, 6v of the simulator 2. In addition, the supply terminal 5w of the control device 2 is switched potential-free, which then likewise applies for the string terminal 6w of the simulator 2. The switching logic 12 has recognized these circumstances, and therefore has closed the virtual switches 11u and 11v and opened the virtual switch 11w.

Switches basically change the structure of a circuit, since circuit parts are generally activated and deactivated by use of switches. The description of a circuit according to equations thus also changes, depending on which of the switches are opened or closed; the circuit is thus structurally variant, and different mathematical models must be used for computing the circuit.

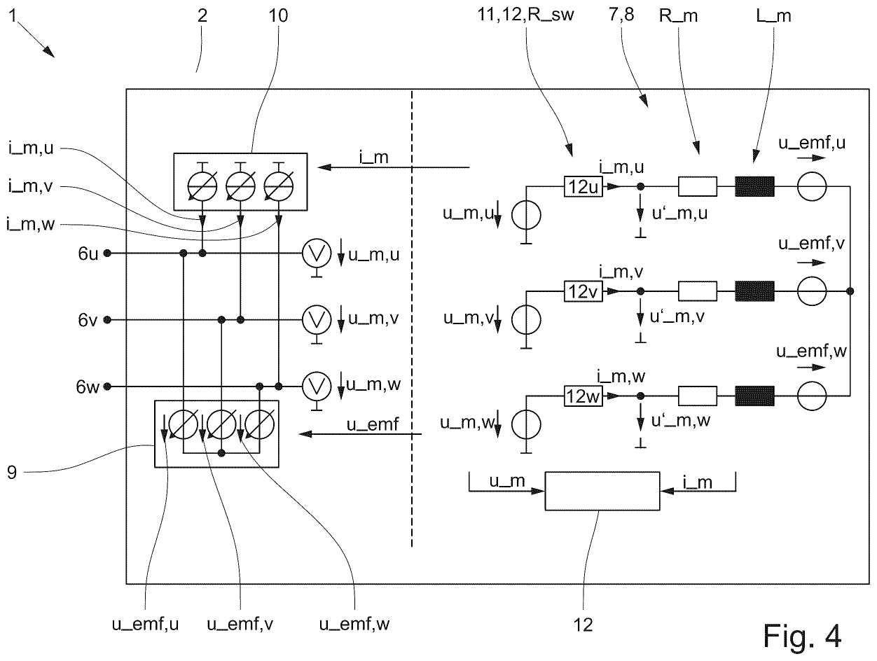

In the example of the method 1 and of the simulator 2 according to FIG. 4, the virtual switches 11 in the models of the strings 8 of the drive are each represented by an ohmic resistor 12 whose resistance values R_sw are a function of the switching state of the virtual switches 11. The mathematical model 8 of the drive is thus structurally invariant, since the mathematical description of the drive does not change with the switching states of the virtual switches 11 (the ohmic resistors 12 are always present, regardless of the switching state), and only parameters of the model, namely, the resistance values R_sw, are a function of the switching states.

The action of the virtual switch 11 in the form of the resistors 12 may be illustrated well by describing the equivalent circuit diagram of the electric drive once again according to equations, as has already been done with reference to FIG. 1, with the difference that the resistance values R_sw of the ohmic resistors 12 must additionally be taken into account. Once again it is assumed that the string terminal 6w is switched potential-free by the control device 3. The resistance values R_sw,u and R_sw,v are set to zero, since the corresponding resistors 12u and 12v represent closed virtual switches 11u, 11v. In addition, the internal string voltages u′_m, which characterize the voltages directly downstream from the resistors 12 of the virtual switches 11, have been introduced, wherein the string voltages u_m are present directly at the other ends of the resistors 12 of the virtual switches 11.

The current in the string 8w, which is switched in a floating manner according to requirements, is given as follows (equation 4):

$$i\_m , w = \frac{u\_m , w - {u}^{′} \_m , w}{R\_sw , w}$$

The internal string voltage u′_m,w of the string 8w, switched potential-free, is given as follows (equation 5):

$${u}^{′} \_m , w = u\_emf , w + \frac{1}{2} ( - u\_emf , u - u\_emf , v + L\_m , u \frac{di\_m , v}{dt} … - L\_m , v \frac{di\_m , v}{dt} + u\_m , u + u\_m , v ) … + 3 R\_m \cdot i\_m , w + ( L\_m , u + 2 L\_m , w ) \frac{di\_m , w}{dt}$$

If the resistance value R_sw,w is selected to be infinitely large, the incorrectly emulated reactive voltage, which is then once again metrologically detected and used as an input variable for the model 7 of the electric drive, no longer has any influence on the current computation. It follows from equation 4 that i_m,w=0 applies. The following expression results from equation 5 (equation 6):

$${u}^{′} \_m , w = u\_emf , w + \frac{1}{2} ( - u\_emf , u - u\_emf , v + L\_m , u \frac{di\_m , v}{dt} … - L\_m , v \frac{di\_m , v}{dt} + u\_m , u + u\_m , v )$$

Equation 6 corresponds to the general result according to equation 2, and therefore represents a correct solution for a magnetically asymmetrical electric drive (in fixed-rotor coordinates, this is synonymous with “Ld not equal to Lq”).

In numerical reality, the resistance value R_sw,w cannot be selected to be infinitely large, for which reason the string current i_m,w is not equal to zero. In the example according to FIG. 4, the computation takes place not according to equation 6, but, rather, according to equation 4 after solving for u′_m,w.

The switching logic 12, which ensures the correctly timed activation of the switches 11 or for the correctly timed change of the resistance values R_sw of the ohmic resistors 12, is implemented in FIG. 4 the same way as with the recognition of the change in circuitry at a string, known per se, on the basis of which the voltage emulator 9 and the current emulator 10 are instructed to energize the potential-loaded strings and to act on the floating string, enabled by the control device 3, with the reactive potential u_emf.

An example of the method 1 and of the simulator 2, provides that the switching logic 12 of the simulator 2 evaluates whether a requirement for correctly determining the reactive potential u_emf,w at the potential-free string terminal 6w is met in the actual operating state of the electric drive, and if the requirement for correctly determining the reactive potential u_emf,w is not met, the switching logic opens the virtual switch 11w of the string 8w whose string terminal 6w is potential-free. In particular, the electric drive being magnetically symmetrical is selected as a requirement for the correct determination of the reactive potential u_emf at the potential-free string terminal 6w.

In the method 1 and the simulator 2 according to FIG. 4, the resistance values R_sw of the virtual switches 11, in the form of the ohmic resistors 12, for the open and the closed switching state are selected in such a way that the mathematical model 7 of the electric drive can be stably solved using explicit numerical solution methods. The values are selected taking a predefined computation increment into account, in particular in such a way that the computation may be carried out in real time.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A computer-implemented method to simulate a multiphase electric drive comprising energizable strings, via a hardware-in-the-loop simulator for testing a power electronic control device with an integrated inverter, the control device comprising at least three supply terminals,
switching, in a test mode, in time segments by the inverter of the control device, one supply terminal of the three supply terminals to a high inverter potential;
switching another supply terminal of the three supply terminals to a low inverter potential; and
switching another supply terminal of the three supply terminals potential-free, wherein in the test mode the supply terminals of the control device are connected to corresponding string terminals of the simulator;
metrologically detecting the string voltages of the string terminals in the simulator;
computing, via the simulator and based on the measured string voltages, corresponding string currents of the drive using a mathematical model of the electric drive and its strings;
evaluating the string voltages and/or string currents in the simulator to determine which string terminal is connected to the potential-free supply terminal of the control device and therefore is a potential-free string terminal;
determining by the simulator an electrical reactive potential of the potential-free string terminal, which results from the drive reaction;
setting, via a voltage emulator, the potential-free string terminal to the determined reactive potential;
feeding, via the simulator, the computed string currents into the nonpotential-free string terminals via a current emulator;
supplementing the mathematical model of the electric drive in the strings in each case by a virtual switch, wherein virtual switches in an open state reduce an influence of the associated measured string voltages on the computed current flows in the particular string; and
opening and/or closing the virtual switches in the strings of the electric drive by a switching logic of the simulator by evaluating at least one string voltage and/or string current.

2. The method according to claim 1, wherein the virtual switch in the model of a string of the drive is represented by an ohmic resistor whose resistance value is a function of the switching state of the virtual switch.

3. The method according to claim 1, wherein the switching logic of the simulator opens the virtual switch of the string whose string terminal is potential-free.

4. The method according to claim 3, wherein the switching logic of the simulator evaluates whether a requirement for correctly determining the reactive potential at the potential-free string terminal is met in the actual operating state of the electric drive, and if the requirement for correctly determining the reactive potential is not met, the switching logic of the simulator opens the virtual switch of the string whose string terminal is potential-free.

5. The method according to claim 4, wherein a requirement for correctly determining the reactive potential at the potential-free string terminal is that the electric drive is magnetically symmetrical.

6. The method according to claim 1, wherein the resistance values of the virtual switches in the form of the ohmic resistors for the open and the closed switching states are selected in such a way that the mathematical model of the electric drive is solved in a stable manner using explicit numerical solution methods or for a predefined computation increment under real-time conditions.

7. The method according to claim 1, wherein the simulated electric drive is a multiphase, or three-phase, permanently excited synchronous machine or a brushless direct current motor.

8. A hardware-in-the-loop simulator for a computer-implemented simulation of a multiphase electric drive comprising energizable strings for testing a power electronic control device comprising an integrated inverter, wherein the control device comprises at least three supply terminals, the simulator comprising:
string terminals; and
a test mode, whereby in time segments, the inverter of the control device:
switches one supply terminal of the three supply terminals to a high inverter potential;
switches another supply terminal of the three supply terminals to a low inverter potential; and
switches yet another supply terminal of the three supply terminals potential-free,
wherein in the test mode, the supply terminals of the control device are connected to the corresponding string terminals of the simulator,
wherein the string voltages of the string terminals in the simulator are metrologically detected,
wherein the simulator, based on the measured string voltages, computes corresponding string currents of the drive using a mathematical model of the electric drive and its strings,
wherein by evaluating the string voltages and/or the string currents, in the simulator it is determined which string terminal is connected to the potential-free supply terminal of the control device and therefore is a potential-free string terminal,
wherein the simulator determines the electrical reactive potential of the potential-free string terminal, which results from the drive reaction, and via a voltage emulator sets the potential-free string terminal to the determined reactive potential,
wherein the simulator feeds the computed string currents into the nonpotential-free string terminals via a current emulator,
wherein the simulator is designed in such a way that in the test mode with the power electronic control device attached, the simulator carries out the method according to claim 1.

9. A computer program that comprises commands which, when the program is executed by a processor of a hardware-in-the-loop simulator, prompts the processing unit to carry out the method according to claim 1.
